(19) United States
(12) Patent Application Publication
(10) Pub. No.: US 2026/0082519 A1
(43) Pub. Date: Mar. 19, 2026

(54) ELECTRONIC DEVICE AND ELECTRONIC RACK

(71) Applicants: INVENTEC (PUDONG) TECHNOLOGY CORPORATION, Shanghai (CN); INVENTEC CORPORATION, Taipei City (TW)

(72) Inventors: Jiang-jun WU, Shanghai (CN); Pin-Yi XIANG, Shanghai City (CN); Xuefeng CHEN, Shanghai City (CN); Yang YING, Shanghai (CN); Yingxiang CUI, Shanghai (CN); Rongqiang WU, Shanghai (CN)

(73) Assignees: INVENTEC (PUDONG) TECHNOLOGY CORPORATION, Shanghai (CN); INVENTEC CORPORATION, Taipei City (TW)

(21) Appl. No.: 18/894,883

(22) Filed: Sep. 24, 2024

(30) Foreign Application Priority Data
Sep. 18, 2024 (CN) 202411303498.9

(51) Int. Cl. H05K 7/20

(52) U.S. Cl. CPC H05K 7/20772; H05K 7/20254; H05K 7/20272; H05K 7/20281

(57) ABSTRACT

An electronic device includes a casing assembly, a motherboard, a first heat source, a first cold plate and a first pipeline. The casing assembly includes a casing, a regulating joint, an outlet joint and an inlet joint. An interior space of the casing accommodates a coolant, the regulating joint, the outlet joint and the inlet joint are disposed on the casing, and the regulating joint and the outlet joint communicate with the interior space. The motherboard is located in the interior space and immersed in the coolant. The first heat source is located in the interior space. The first cold plate is thermally coupled to the first heat source. The first cold plate has a first inlet and a first outlet, and the first outlet communicates with the interior space. The first pipeline is connected to the inlet joint and the first inlet of the first cold plate.

### CROSS-REFERENCE TO RELATED APPLICATIONS

This non-provisional application claims priority under 35 U.S. C. § 119(a) on Patent Application No(s). 202411303498.9 filed in China, on September 18, 2024, the entire contents of which are hereby incorporated by reference.

### BACKGROUND OF THE INVENTION

### Technical Field of the Invention

The invention relates to an electronic device and an electronic rack.

### Description of the Related Art

Currently, electronic devices, such as servers, have adopted liquid cooling means for heat dissipation. Generally, the servers are directly immersed by a dielectric coolant in a tank. The dielectric coolant absorbs heat generated by multiple heat sources in each server and takes heat away. However, filling the dielectric coolant in the tank for immersing the servers uses too much dielectric coolant, which will lead to high cost, and is unable to concentrate the dielectric coolant on cooling the heat sources who generate greater amount of heat. Therefore, how to address the aforementioned issues is one of topics in this field.

### SUMMARY OF THE INVENTION

The invention provides an electronic device and an electronic rack which can reduce an amount of the coolant and increase the heat dissipation efficiency to the heat sources who generate greater amount of heat.

One embodiment of the invention provides an electronic device. The electronic device is adapted to accommodate a coolant. The electronic device includes a casing assembly, a motherboard, a first heat source, a first cold plate and a first pipeline. The casing assembly includes a casing, a regulating joint, an outlet joint and an inlet joint. The casing has an interior space, the interior space has a liquid chamber and a gas chamber communicating with each other, the liquid chamber is configured to accommodate the coolant, the regulating joint, the outlet joint and the inlet joint are disposed on the casing, and the regulating joint and the outlet joint communicate with the interior space. The motherboard is located in the liquid chamber and configured to be at least partially immersed in the coolant. The first heat source is located in the liquid chamber and electrically connected to the motherboard. The first cold plate is thermally coupled to the first heat source. The first cold plate has a first inlet and a first outlet, and the first outlet of the first cold plate communicates with the interior space of the casing. The first pipeline is connected to the inlet joint and the first inlet of the first cold plate.

Another embodiment of the invention provides an electronic rack. The electronic rack includes a rack and an electronic device. The electronic device is disposed in the rack and includes a casing assembly, a motherboard, a first heat source, a first cold plate and a first pipeline. The casing assembly includes a casing, a regulating joint, an outlet joint and an inlet joint. The casing has an interior space, the interior space has a liquid chamber and a gas chamber communicating with each other, the liquid chamber is configured to accommodate a coolant, the regulating joint, the outlet joint and the inlet joint are disposed on the casing, and the regulating joint and the outlet joint communicate with the interior space. The motherboard is located in the liquid chamber and configured to be at least partially immersed in the coolant. The first heat source is located in the liquid chamber and electrically connected to the motherboard. The first cold plate is thermally coupled to the first heat source, the first cold plate has a first inlet and a first outlet, and the first outlet of the first cold plate communicates with the interior space of the casing. The first pipeline is connected to the inlet joint and the first inlet of the first cold plate.

According to the electronic device and the electronic rack as discussed in the above embodiments, the interior space of the casing of each electronic device in the rack has the liquid chamber for accommodating the coolant, and the motherboard in the liquid chamber is at least partially immersed in the coolant, which can save the amount of the coolant compared to a case that one tank is filled with the coolant for immersing all of the motherboards of the electronic devices.

In addition, the first cold plate is thermally coupled to the first heat source in the liquid chamber, the inlet joint is connected to the first inlet of the first cold plate via the first pipeline, and the first outlet of the first cold plate communicates with the interior space of the casing, which enables the cool coolant to firstly passes through the first cold plate to take away heat generated by the first heat source, then the coolant enters into the interior space of the casing, and thus the heat dissipation efficiency to the first heat source can be improved.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a cross-sectional view of an electronic rack according to one embodiment of the invention;

FIG. 2 is an exploded view of an electronic device in FIG. 1; and

FIG. 3 is a cross-sectional view of the electronic device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

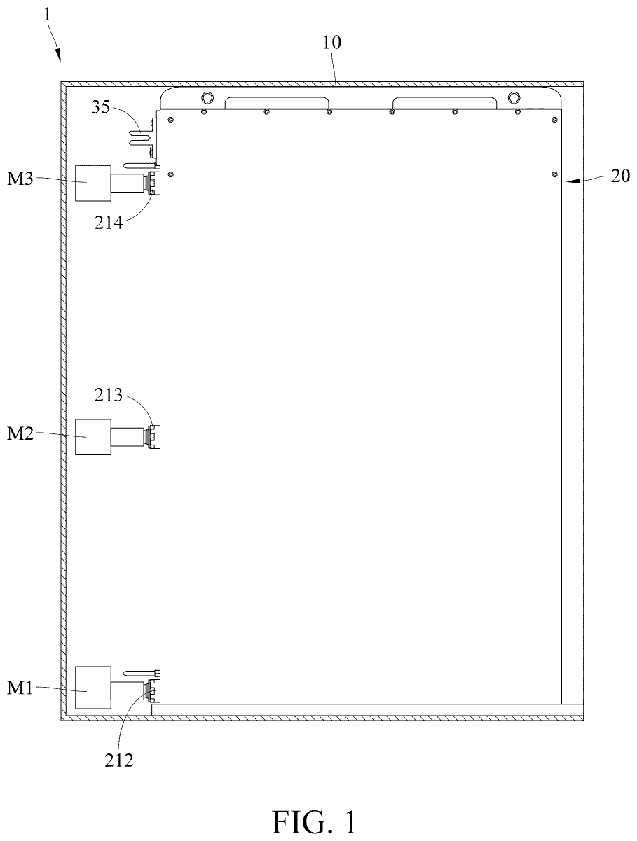

Referring to FIG. 1, FIG. 1 is a cross-sectional view of an electronic rack according to one embodiment of the invention.

In this embodiment, the electronic rack 1 includes a rack 10 and at least one electronic device 20 accommodated in the rack 10. Although FIG. 1 merely shows there is one electronic device 20 disposed in the rack 10, the rack 10 may actually accommodate multiple electronic devices 20, and the electronic devices 20 are, for example, arranged side by side.

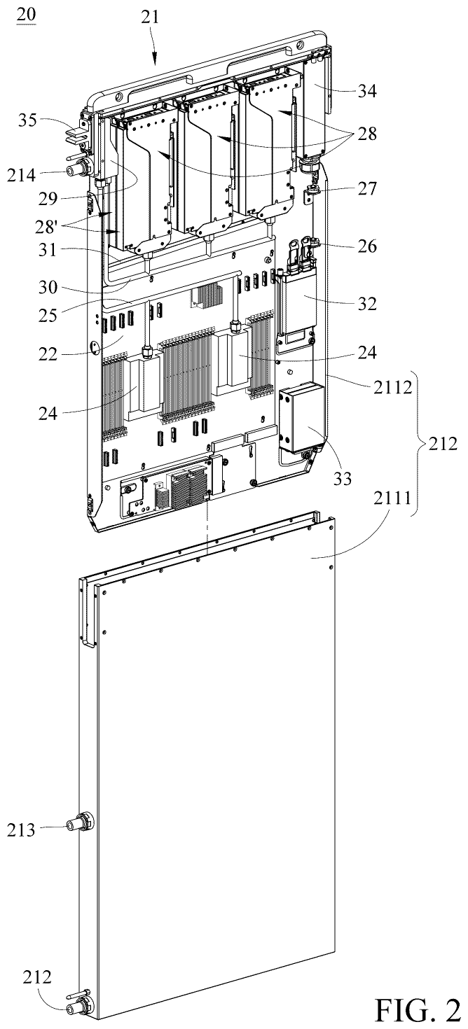

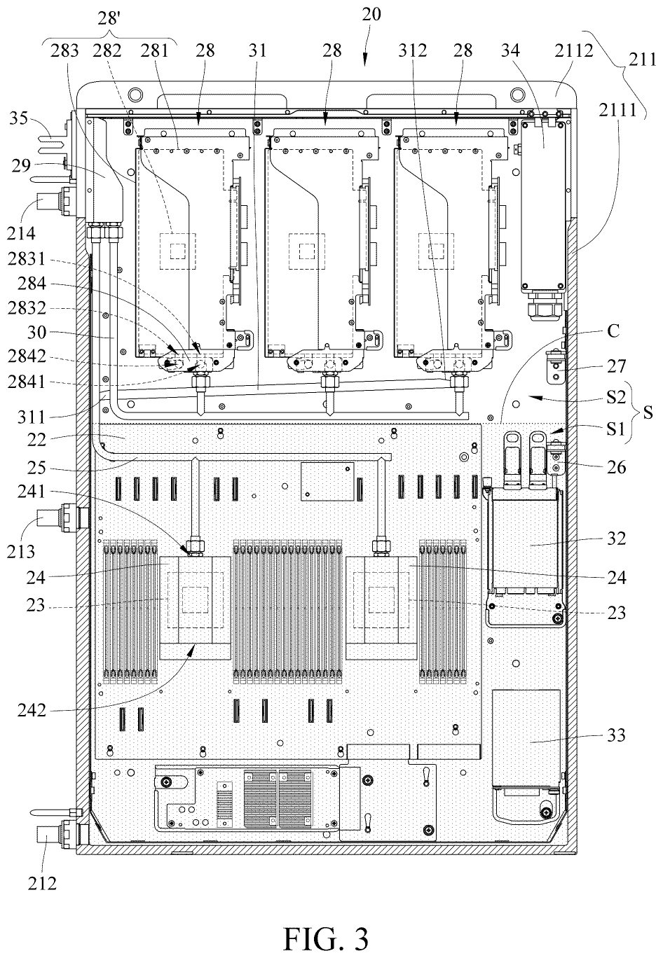

Then, the following paragraphs will specifically introduce the electronic device 20. Referring to FIGS. 1 to 3, FIG. 2 is an exploded view of an electronic device in FIG. 1, and FIG. 3 is a cross-sectional view of the electronic device in FIG. 1.

The electronic device 20 is, for example, a server. The electronic device 20 includes a casing assembly 21, a motherboard 22, two first heat sources 23, two first cold plates 24 and a first pipeline 25.

The casing assembly 21 includes a casing 211, a regulating joint 212, an outlet joint 213 and an inlet joint 214. The casing 211 includes a housing 2111 and a tray 2112. Walls of the housing 2111 are connected to each other in a sealed manner. The tray 2112 is movably mounted in the housing 2111. The tray 2112 and the housing 2111 together form an interior space S. The interior space S has a liquid chamber S1 and a gas chamber S2 communicating with each other. The liquid chamber S1 is a portion of the interior space S for accommodating a coolant C, where the coolant C is, for example, dielectric fluid, such as synthetic oil or silicone oil with lower cost.

The regulating joint 212 and the outlet joint 213 are disposed on a same side of the housing 2111 and directly communicate with the interior space S, such as the liquid chamber S1. The regulating joint 212 is located closer to a bottom of the housing 2111 than the outlet joint 213. The regulating joint 212 is configured to be connected to a regulating manifold M1 in the rack 10. The regulating manifold M1 can deliver the coolant C into the interior space S through the regulating joint 212, and the coolant C in the interior space S can flow into the regulating manifold M1 from the regulating joint 212 for adjusting the liquid level of the coolant C in the interior space S. The outlet joint 213 is configured to be connected to a discharge manifold M2 in the rack 10. The outlet joint 213 enables the coolant C in the interior space S to flow into the discharge manifold M2 from the electronic device 20. The inlet joint 214 is disposed on the tray 2112, and the inlet joint 214, the regulating joint 212 and the outlet joint 213 are located at a same side of the casing 211, and the inlet joint 214 is located farther away from the bottom of the housing 2111 than the regulating joint 212 and the outlet joint 213. The inlet joint 214 is configured to be connected to a supply manifold M3 in the rack 10, and the inlet joint 214 does not directly communicate with the interior space S.

The motherboard 22 is located in the liquid chamber S1 and is disposed on the tray 2112, and the motherboard 22 is configured to be at least partially immersed in the coolant C. In this embodiment, the motherboard 22 is, for example but not limited to, entirely immersed in the coolant C, where the liquid level of the coolant C is flush with an upper edge of the motherboard 22 located farther away from the bottom of the housing 2111. As a result, electronic components (e.g., memories or controllers) on the motherboard 22 are also immersed in the coolant C so as to be cooled by the coolant C.

The first heat sources 23 are, for example, CPUs. The first heat sources 23 are located in the liquid chamber S1 and are disposed on the motherboard 22 so as to be disposed on the tray 2112 via the motherboard 22. The first heat sources 23 are electrically connected to the motherboard 22. The first cold plates 24 are stacked on the first heat sources 23 so as to be thermally coupled to the first heat sources 23, respectively. In other words, heat generated by the first heat sources 23 can be conducted to the first cold plates 24. Each of the first cold plate 24 has a first inlet 241 and a first outlet 242. One end of the first pipeline 25 is connected to the inlet joint 214, and the first pipeline 25 has two branches respectively connected to the first inlets 241 of the first cold plates 24. The first outlets 242 of the first cold plates 24 directly communicate with the liquid chamber S1.

Note that the quantities of the first heat sources 23 and the first cold plates 24 are not restricted in the invention. In some other embodiments, the electronic device may include a single first heat source and a single first cold plate.

In this embodiment, the electronic device 20 may further include a first liquid level sensor 26 and a second liquid level sensor 27. The first liquid level sensor 26 and the second liquid level sensor 27 are respectively located in the liquid chamber S1 and the gas chamber S2 of the interior space S, and the first liquid level sensor 26 and the second liquid level sensor 27 are spaced apart from the bottom of the housing 2111 by different distances, where the first liquid level sensor 26 is, for example, located closer to the bottom of the housing 2111 than the second liquid level sensor 27. When the liquid level of the coolant C is lower than the first liquid level sensor 26, the first liquid level sensor 26, for example, transmits a low level signal to a baseboard management controller (not shown) on the motherboard 22 to warm that the coolant is required to be replenished for increasing the liquid level of the coolant C. In contrast, when the liquid level of the coolant C is higher than the second liquid level sensor 27, the second liquid level sensor 27, for example, transmits a high level signal to the baseboard management controller on the motherboard 22 to warm that the coolant C is required to be extracted for decreasing the liquid level of the coolant C.

In this embodiment, the electronic device 20 may further include a plurality of electronic modules 28, a coolant distributor 29, a second pipeline 30 and a guiding component 31.

The electronic modules 28 are disposed on the tray 2112 and are located in the gas chamber S2 of the interior space S. The electronic modules 28 have the same structure, and the later descriptions merely introduces one of them in detail. The electronic module 28 is, for example but not limited to, a graphics card module and includes two electronic assemblies 28′ and a liquid distribution component 284. Taking one electronic assembly 28′ for example, the electronic assembly 28′ is a graphics card assembly and includes a circuit board 281, a second heat source 282 and a second cold plate 283. The circuit board 281 is electrically connected to the motherboard 22, and the second heat source 282 is, for example, a GPU and is disposed on the circuit board 281. The second cold plate 283 is thermally coupled to the second heat source 282. The second cold plate 283 has a second inlet 2831 and a second outlet 2832. The liquid distribution component 284 has an inlet 2841 and an outlet 2842. The inlet 2841 of the liquid distribution component 284 communicates with the second inlet 2831 of the second cold plate 283, and the second outlet 2832 of the second cold plate 283 communicates with the outlet 2842 of the liquid distribution component 284, where the outlet 2842 of the liquid distribution component 284 directly communicates with the gas chamber S2.

The coolant distributor 29 is disposed on the tray 2112 and is located in the gas chamber S2. The coolant distributor 29 is connected to the inlet joint 214, one end of the first pipeline 25 and one end of the second pipeline 30. The second pipeline 30 has a plurality of branches respectively connected to the inlets 2841 of the liquid distribution components 284 of the electronic modules 28.

Note that the quantity of the electronic modules 28 is not restricted in the invention. In some other embodiments, the electronic device may include a single electronic module. In addition, the electronic module 28 is not restricted including two electronic assemblies 28′. In some other embodiments, the electronic module may include a single electronic assembly and omit the liquid distribution component, the second pipeline may be directly connected to the second inlet of the second cold plate, and the second outlet of the second cold plate may directly communicate with the gas chamber. On other hand, the coolant distributor 29, the second pipeline 30 and the electronic modules 28 are optional components and may be omitted in some other embodiments.

The guiding component 31, for example, has a groove structure. The guiding component 31 is disposed in the gas chamber S2 and is located between the first cold plates 24 and the second cold plates 283. The guiding component 31 is located farther away from the bottom of the housing 2111 than the outlet joint 213, and is located closer to the bottom of the housing 2111 than the second cold plates 283. The guiding component 31 has a first end 311 and a second end 312 located opposite to each other. The first end 311 is located closer to the bottom of the housing 2111 than the second end 312, and the first end 311 is located closer to the outlet joint 213 than the second end 312. The guiding component 31 is configured to guide the coolant C flowing out of the second cold plates 283 of the electronic modules 28 towards the outlet joint 213.

In this embodiment, the electronic device 20 may further include a plurality of third heat sources 32 and 33. The third heat sources 32 and 33 are, for example, a network interface card module and a storage module. The third heat sources 32 and 33 are disposed on the tray 2112, and the third heat sources 32 and 33 are located in the liquid chamber S1 and are immersed in the coolant C. An amount of heat generated by each of the third heat sources 32 and 33 is fewer than an amount of heat generated by each of the first heat sources 23 and an amount of heat generated by each of the second heat sources 282.

In this embodiment, the electronic device 20 may further include a signal transmission connector 34 and a power connector 35. The signal transmission connector 34 and the power connector 35 are disposed on two opposite sides of the tray 2112 of the casing 211, and the power connector 35 and the inlet joint 214 are located at the same side of the casing 211. The signal transmission connector 34 and the power connector 35 are electrically connected to the motherboard 22. The signal transmission connector 34 is configured to be in signal communication with an external device. The power connector 35 is, for example, assembled with a busbar (not shown) in the rack 10. The busbar in the rack 10 can transmit a voltage approximate to a voltage required by the electronic device 20, or directly transmit a voltage required by the electronic device 20. As a result, the electronic device 20 may adopt a smaller power module, or may not include a power module, thereby saving the cost and the space of the electronic device 20.

In this embodiment, the interior space S of the casing 211 of each of the electronic devices 20 in the rack 10 has the liquid chamber S1 for accommodating the coolant C, and the motherboard 22 in the liquid chamber S1 is at least partially immersed in the coolant C, which can save the amount of the coolant C compared to a case that one tank is filled with the coolant for immersing all of the motherboards of the electronic devices. For example, the tank is generally filled with 800L of coolant, and the tank can accommodate 52 electronic devices in maximum, such that one electronic device requires 15.38 L of coolant in average. As for this embodiment, one electronic device 20 approximately requires 5 L to 6 L of coolant C, thereby saving above 60% coolant C and thus saving cost.

In this embodiment, the cold coolant C delivered to the coolant distributor 29 by the supply manifold M3 can be delivered to the first cold plates 24 and the second cold plates 283 through the first pipeline 25 and the second pipeline 30 so as to take away heat absorbed by the first cold plates 24 from the first heat sources 23 and heat absorbed by the second cold plates 283 from the second heat sources 282. Then, the coolant C flowing out of the first cold plates 24 from the first outlets 242 enters into the liquid chamber S1, and the coolant C flowing out of the second cold plates 283 from the second outlet 2832 enters into the gas chamber S2. In other words, the cool coolant C firstly passes through the first cold plates 24 and the second cold plates 283 to take away a greater amount of heat generated by the first heat sources 23 and the second heat sources 282, then the coolant C enters into the interior space S of the casing 211, and thus the heat dissipation efficiencies to the first heat sources 23 and the second heat sources 282 can be improved.

In this embodiment, after the coolant C flowing out of the first cold plates 24 from the first outlets 242 enters into the liquid chamber S1, the coolant C will cool other heat sources (e.g., the third heat sources 32 and 33) along with the coolant C originally existing in the liquid chamber S1, and then flows out of the electronic device 20 from the outlet joint 213.

In this embodiment, after the coolant C flowing out of the second cold plates 283 from the second outlets 2832 enters into the gas chamber S2, the coolant C will drop on the guiding component 31, and the guiding component 31 guides the coolant C towards the outlet joint 213. The guiding component 31 not only guides the hot coolant C flowing out of the second cold plates 283 to the outlet joint 213 for leaving the electronic device 20, but also prevents the hot coolant C flowing out of the second cold plates 283 from directly flowing towards the first heat sources 23 and the motherboard 22 located below the second cold plates 283, thereby ensuring the hot coolant C from the second cold plates 283 does not affect the heat dissipation of the first heat sources 23 and the electronic components on the motherboard 22.

Note that the guiding component 31 is an optional component. When the coolant flowing out of the second cold plates from the second outlets does not affect the heat dissipation of other components, the guiding component may be omitted.

In this embodiment, when the electronic device 20 is required to be maintained, the coolant C is required to be firstly extracted out of the electronic device 20 from the regulating joint 212, then the electronic device 20 is drawn out of the rack 10, and then the tray 2112 is drawn out of the housing 2111. As a result, the components and the modules (e.g., the motherboard 22, the first heat sources 23, the electronic modules 28, the third heat sources 32 and 33 and so on) on the tray 2112 may be separated from the housing 2111 along with the tray 2112. Therefore, not only the maintenance of single one electronic device 20 is realized, but also the process of the maintenance of the electronic device 20 is simple and efficient while the lost, the volatilization and the pollution of the coolant C can be reduced as much as possible.

In this embodiment, the electronic device 20 in the electronic rack 1 is vertically placed in the rack 10, and the electronic device 20 can be installed in or removed from the rack 10 horizontally, which facilitates the space arrangement of a data center where the electronic rack 1 is located.

According to the electronic device and the electronic rack as discussed in the above embodiment, the interior space of the casing of each of the electronic devices in the rack has the liquid chamber for accommodating the coolant, and the motherboard in the liquid chamber is at least partially immersed in the coolant, which can save the amount of the coolant compared to a case that one tank is filled with the coolant for immersing all of the motherboards of the electronic devices.

In addition, the first cold plates are thermally coupled to the first heat sources in the liquid chamber, the second cold plates are thermally coupled to the second heat sources in the gas chamber, the inlet joint is connected to the first inlets of the first cold plates and the second inlets of the second cold plates via the first pipeline and the second pipeline, respectively, and the first outlets of the first cold plates and the second outlets of the second cold plates communicate with the interior space of the casing, which enables the cool coolant to firstly passes through the first cold plates and the second cold plates to take away heat generated by the first heat sources and the second heat sources, then the coolant enters into the interior space of the casing, and thus the heat dissipation efficiencies to the first heat sources and the second heat sources can be improved.

Moreover, after the coolant flowing out of the second cold plates from the second outlets enters into the gas chamber, the coolant will drop on the guiding component, and the guiding component guides the coolant towards the outlet joint. The guiding component not only guides the hot coolant flowing out of the second cold plates to the outlet joint for leaving the electronic device, but also prevents the hot coolant flowing out of the second cold plates from directly flowing towards the first heat sources and the motherboard located below the second cold plates, thereby ensuring the hot coolant from the second cold plates does not affect the heat dissipation of the first heat sources and the electronic components on the motherboard.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An electronic device, adapted to accommodate a coolant, comprising:
a casing assembly, comprising a casing, a regulating joint, an outlet joint and an inlet joint, wherein the casing has an interior space, the interior space has a liquid chamber and a gas chamber communicating with each other, the liquid chamber is configured to accommodate the coolant, the regulating joint, the outlet joint and the inlet joint are disposed on the casing, and the regulating joint and the outlet joint communicate with the interior space;
a motherboard, located in the liquid chamber and configured to be at least partially immersed in the coolant;
a first heat source, located in the liquid chamber and electrically connected to the motherboard;
a first cold plate, thermally coupled to the first heat source, wherein the first cold plate has a first inlet and a first outlet, and the first outlet of the first cold plate communicates with the interior space of the casing; and
a first pipeline, connected to the inlet joint and the first inlet of the first cold plate.

2. The electronic device according to claim 1, further comprising an electronic module and a second pipeline, wherein the electronic module is located in the gas chamber and comprises a circuit board, a second heat source and a second cold plate, the circuit board is electrically connected to the motherboard, the second heat source is disposed on the circuit board, the second cold plate is thermally coupled to the second heat source, the second cold plate has a second inlet and a second outlet, the second outlet of the second cold plate communicates with the interior space of the casing, and the second pipeline is connected to the inlet joint and the second inlet of the second cold plate.

3. The electronic device according to claim 2, wherein the first heat source is disposed on the motherboard, the second heat source is located farther away from a bottom of the casing than the first heat source, the outlet joint is located farther away from the bottom of the casing than the first cold plate and is located closer to the bottom of the casing than the second cold plate.

4. The electronic device according to claim 3, further comprising a guiding component, wherein the guiding component is disposed in the gas chamber and located between the first cold plate and the second cold plate, the guiding component has a first end and a second end located opposite to each other, the first end is located closer to the bottom of the casing than the second end, and the first end is located closer to the outlet joint than the second end.

5. The electronic device according to claim 4, wherein the guiding component is located farther away from the bottom of the casing than the outlet joint and is located closer to the bottom of the casing than the second cold plate.

6. The electronic device according to claim 2, further comprising a coolant distributor, wherein the coolant distributor is disposed in the gas chamber of the casing, the inlet joint is connected to the first pipeline and the second pipeline via the coolant distributor.

7. The electronic device according to claim 2, further comprising a third heat source, wherein the third heat source is located in the liquid chamber and is electrically connected to the motherboard, an amount of heat generated by the third heat source is fewer than an amount of heat generated by the first heat source and an amount of heat generated by the second heat source, and the third heat source is configured to be immersed in the coolant.

8. The electronic device according to claim 1, further comprising a first liquid level sensor and a second liquid level sensor, wherein the first liquid level sensor and the second liquid level sensor are respectively located in the liquid chamber and the gas chamber of the interior space, and the first liquid level sensor and the second liquid level sensor are spaced apart from a bottom of the casing by different distances.

9. The electronic device according to claim 1, wherein the casing comprises a housing and a tray, the tray is movably mounted in the housing, the tray and the housing together form the interior space, the regulating joint and the outlet joint are disposed on the housing, and the inlet joint, the motherboard, the first heat source, the first cold plate and the first pipeline are disposed on the tray.

10. The electronic device according to claim 1, further comprising a signal transmission connector and a power connector, wherein the signal transmission connector and the power connector are disposed on the casing and are electrically connected to the motherboard.

11. An electronic rack, comprising:
a rack; and
an electronic device, disposed in the rack and comprising:
a casing assembly, comprising a casing, a regulating joint, an outlet joint and an inlet joint, wherein the casing has an interior space, the interior space has a liquid chamber and a gas chamber communicating with each other, the liquid chamber is configured to accommodate a coolant, the regulating joint, the outlet joint and the inlet joint are disposed on the casing, and the regulating joint and the outlet joint communicate with the interior space;
a motherboard, located in the liquid chamber and configured to be at least partially immersed in the coolant;
a first heat source, located in the liquid chamber and electrically connected to the motherboard;
a first cold plate, thermally coupled to the first heat source, wherein the first cold plate has a first inlet and a first outlet, and the first outlet of the first cold plate communicates with the interior space of the casing; and
a first pipeline, connected to the inlet joint and the first inlet of the first cold plate.
